(19) United States
(12) Patent Application Publication
(10) Pub. No.: US 2020/0141986 A1
(43) Pub. Date: May 7, 2020

(54) Filter Configured to Detect Specific Frequencies of a Monitored Signal

(71) Applicant: Jaber Technology Holdings US Inc., Wimberley, TX (US)

(72) Inventors: Marwan A. Jaber, Saint-Leonard (CA); Radwan A. Jaber, Saint-Leonard (CA); Daniel Massicotte, Trois-Rivieres (CA)

(73) Assignee: Jaber Technology Holdings US Inc., Wimberley, TX (US)

(21) Appl. No.: 16/425,130

(22) Filed: May 29, 2019

Related U.S. Application Data
(60) Provisional application No. 62/677,587, filed on May 29, 2018.

(51) Int. Cl. G01R 23/167; G01R 23/02; G06F 17/14

(52) U.S. Cl. CPC G01R 23/167; G06F 17/142; G01R 23/02

(57) ABSTRACT

In some embodiments, a circuit may include an input configured to receive a signal and a radix-r fast Fourier transform (FFT) processing element coupled to the input. The radix-r FFT processing element may be configured to subdivide data of size N into r equal sub-domains of size N/r−1 to determine specific frequencies.

### CROSS-REFERENCE TO RELATED APPLICATION(S)

The present disclosure is a non-provisional of and claims priority to U.S. Provisional Patent Application No. 62/677,587 filed on May 29, 2018 and entitled “Filter Configured to Detect Specific Frequencies of a Monitored Signal”, which is incorporated herein by reference in its entirety.

### FIELD

The present disclosure is generally related to filters that may be implemented in software or hardware, and more particularly to filters configured to detect specific frequencies of a monitored signal.

### BACKGROUND

Digital Signal Processing (DSP) is generally concerned with the representation and manipulation of signals in digital form. The discipline of signal processing, whether analog or digital, consists of a large number of specific techniques. One of the most important techniques includes the signal-analysis/feature-extraction technique, which aims to extract useful information from a given monitored signal.

Signal monitoring generally relates to the detection of any abrupt changes for a known frequency. Such signal monitoring is often used in fault detection or to scan a pre-selected set of frequencies, as in radio-frequency identification (RFID) tags. Further, such signal monitoring can include recognition of the dual-tone multi-frequency (DTMF) signaling, and other signals.

### SUMMARY

A Discrete Fourier Transform (DFT) is a mathematical procedure that is frequently used inside of digital signal processors (DSPs). In some embodiments, systems, methods, and devices may be configured to implement a fast Fourier transform (FFT) to detect specific frequencies in a monitored signal, providing gains in computational speeds.

In some embodiments, a circuit may include an input configured to receive a signal and a radix-r fast Fourier transform (FFT) processing element coupled to the input. The radix-r FFT processing element may be configured to subdivide data of size N into r equal sub-domains of size N/r−1 to determine specific frequencies.

In one possible embodiment, a circuit may include an input configured to receive a signal and a radix-r fast Fourier transform (FFT) processing element coupled to the input. The radix-r FFT processing element may be configured to subdivide data of size N into r equal sub-domains of size N/r−1 and to process the r equal subdomains in parallel to determine r specific frequencies. The circuit may further include a radix-r butterfly to combine the r specific frequencies to determine an output frequency.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items or features.

FIG. 1 depicts a block diagram of a first-order Goertzel algorithm.

FIG. 2 depicts a block diagram of the second order Goertzel algorithm.

FIG. 3 depicts a block diagram of a radix-r first-order filter according to some embodiments.

FIG. 4 depicts a block diagram of a radix-r second-order filter according to some embodiments.

FIG. 5 depicts a radix-2 first-order filter according to some embodiments.

FIG. 6 depicts a radix-2 second-order filter according to some embodiments.

FIG. 7 depicts a radix-4 first-order filter according to some embodiments.

FIG. 8 depicts a radix-4 second-order filter according to some embodiments.

FIG. 9 depicts a radix-8 first-order filter according to some embodiments.

FIG. 10 depicts a radix-8 second-order filter according to some embodiments.

FIG. 11 depicts a parallel implementation of the radix-r first and second order filter to detect a specific frequency in one-dimension according to some embodiments.

FIG. 12 depicts a parallel implementation of the radix-2 first and second order filter to detect a specific frequency in one-dimension according to some embodiments.

FIG. 13 depicts a parallel implementation of the radix-4 first and second order filter to detect a specific frequency in one-dimension according to some embodiments.

FIG. 14 depicts a parallel implementation of the radix-8 first and second order filter to detect a specific frequency in one-dimension according to some embodiments.

FIG. 15 depicts a parallel implementation of the radix-r first and second order filter to detect a specific frequency in two-dimensional space according to some embodiments.

FIG. 16 depicts a parallel implementation of the radix-r first and second order filter to detect a specific frequency in three-dimensional space according to some embodiments.

FIG. 17 depicts a block diagram of a fixed-point simulation with Quadrature Phase Shift Keying (QPSK) according to some embodiments.

FIG. 18 depicts a graph of Signal-to-Quantization-Noise Ratio (SQNR) versus a logarithm of the number of iterations for first and second order filters according to some embodiments.

FIG. 19 depicts a block diagram of a system including a radix-r FFT circuit according to some embodiments.

While implementations are described in this disclosure by way of example, those skilled in the art will recognize that the implementations are not limited to the examples or figures described. It should be understood that the figures and detailed description thereto are not intended to limit implementations to the particular form disclosed but, on the contrary, the intention is to cover all modifications, equivalents, and alternatives falling within the spirit and scope as defined by the appended claims. The headings used in this disclosure are for organizational purposes only and are not meant to be used to limit the scope of the description or the claims. As used throughout this application, the word “may” is used in a permissive sense (i.e., meaning having the potential to) rather than the mandatory sense (i.e., meaning must). Similarly, the words “include”, “including”, and “includes” mean “including, but not limited to”.

### DETAILED DESCRIPTION OF ILLUSTRATIVE EMBODIMENTS

Embodiments of systems, methods, and devices are described below that may use an efficient FFT-based method to detect specific frequencies in a monitored signal. The detected signals may be compared to thresholds, to known signals patterns, and so on to determine data. In one example, signal processing may detect any abrupt changes in a specific known frequency, such as in a Fault Detection Machine. In another example, the signal processing may be used to scan a pre-selected set of frequencies, as in radio-frequency identification (RFID) tags. In another example, the signal monitoring may be used to determine information from the dual-tone multi-frequency (DTMF) signaling. In still another example, the signal monitoring may be used for induction motor fault detection using space vector angular fluctuation. In still another example, the signal monitoring may be used for detection of coding regions in large DNA sequences. Additionally, the signal monitoring may be used for mechanical fault diagnosis or other mechanical detection by looking for changes or patterns at particular frequencies or within pre-determined frequency ranges.

In other examples, the systems, methods, and devices may use the efficient FFT-based method in conjunction with heterodyning to detect particular signals or particular frequencies. Heterodyning refers to a technique that creates new frequencies by combining or mixing two frequencies. For example, heterodyning can be used to shift one frequency range of a signal into another, new frequency range.

In still other examples, embodiments of systems, methods and devices described below may use the efficient FFT-based method to determine magnetic fields, radio frequency signals, radiation, and signature frequencies within radar or sonar or other signals. In an example, the efficient FFT-based method may be used to detect emerging weather patterns in radar data.

In still other examples, the embodiments of systems, methods, and devices can be used to deliberately block or interfere with radio frequency signals to disrupt communications by decreasing the signal-to-noise ratio. In still other examples, embodiments of the systems, methods, and devices may use the efficient FFT-based method for detection, analysis and classification of high frequency oscillations in various signals, such as electroencephalographic signals, seismic signals, brain-wave signals, and so on. In one possible example, the efficient FFT-based method may be used to detect changes in brain-wave signals that may be indicative of early seizure activity for early detection of epileptic events.

Embodiments of the systems, methods, and devices may also be used for multidimensional infrared (IR) spectroscopy, in light detection and ranging (LIDAR), in motion detection, and so on. LIDAR refers to a surveying method that measures distance to a target by illuminating the target with pulsed laser light and by measuring the reflected pulses with a sensor. The system may provide motion detection and estimation in the two-dimensional and three-dimensional space. Other uses and other implementations are also possible.

There are various ways to detect the presence of a specific frequency in a monitored signal. The FFT algorithm may require the highest amount of complex multiplications to compute a specific frequency X₍ₖ₎, plus an extra memory of size N, which may be used to store an intermediate result. A direct computation of the DFT may require less complex multiplication than the FFT with no need of the extra memory of size N to store the intermediate results. In particular, a modified version of Goertzel's algorithm, as described below, may provide an efficient method (in terms of multiplications and memories) for computing X₍ₖ₎.

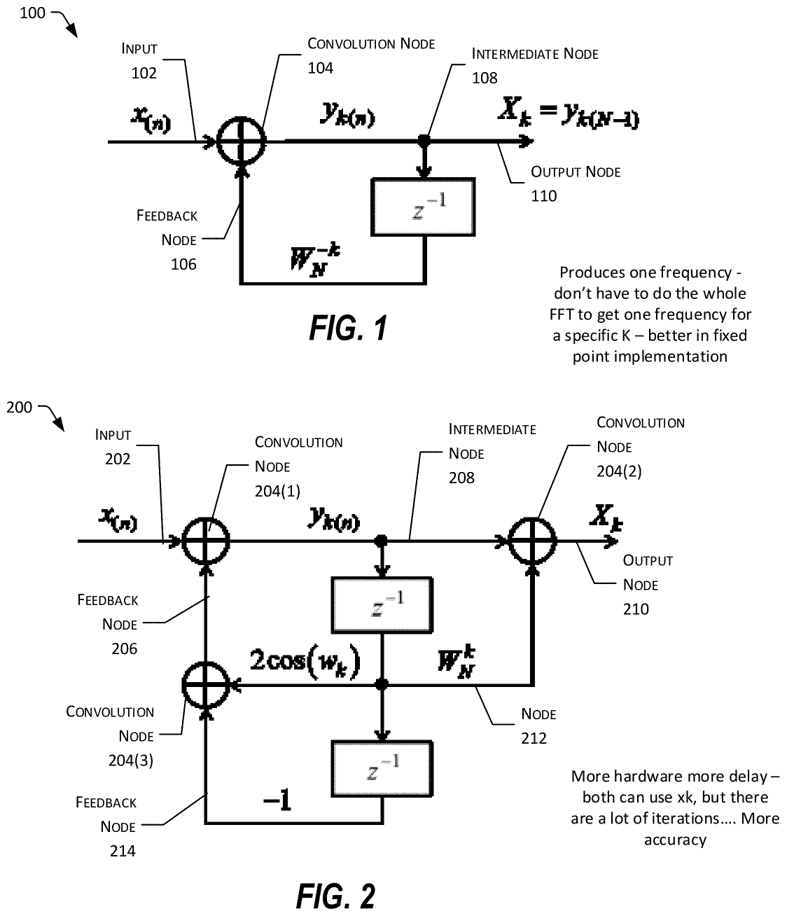

The derivation of a first-order Goertzel algorithm begins by noting that the DFT can be formulated in terms of a convolution. In an example, the DFT of signal x₍ₖ₎x₍ₖ₎ can be represented as follows:

$${X}_{( k )} {\sum }_{n = 0}^{N - 1} {x}_{( n )} {w}_{N}^{nk} , \\ {w}_{N}^{k} = {e}^{- j \frac{2 π k}{N}} = {\sum }_{n = 0}^{N - 1} {x}_{( n )} {w}_{N}^{- k ( N - n )} , \\ {w}_{N}^{- kN} = 1 = {x}_{( n )} * {h}_{( n )} {\vert}_{n = N} , \\ {X}_{( k )} = {\sum }_{n = 0}^{N - 1} {x}_{( n )} {w}_{N}^{nk} , \\ {w}_{N}^{k} = {e}^{- j \frac{2 π k}{N}} = {\sum }_{n = 0}^{N - 1} {x}_{( n )} {w}_{N}^{- k ( N - n )} , \\ {w}_{N}^{- kN} = 1 = {x}_{( n )} * {h}_{( n )} {\vert}_{n = N} , , \qquad ( Equation 1 )$$

where the symbol “*” represents the convolution product of signal x₍ₙ₎x₍ₙ₎ through a linear time invariant (LTI) filter with impulse response h₍ₙ₎=w^{-nk}u₍ₙ₎h₍ₙ₎=w^{-nk}u₍ₙ₎ and evaluating the result, yₖ₍ₙ₎, at n=N as described below with respect to FIG. 1.

FIG. 1 depicts a block diagram 100 of a first-order Goertzel algorithm. The diagram 100 includes an input 102 to receive a signal x(n), which is convolved with an impulse response filter W_{N}^{-k} to produce an output signal Xₖ according to flow graph depicted in FIG. 1. The input 102 may be coupled to a first input of a convolution node 104, which has a second input coupled to a feedback node 106, and an output coupled to an intermediate node 108. The diagram 100 may further include an output node 110. The intermediate node 108 may be coupled to the feedback node 106 via a Z-transform.

The recurrent equations of the transform can be written as follows:

yₖ_{₍ₙ₎}=W_{N}^{-k}yₖ_{_{(n−1)}}+x₍ₙ₎ , (Equation 2)

and the filter's output for the k^{th} frequency is

Xₖ=yₖ_{_{(N−1)}} ,(Equation 3)

where W_{N}=e^{-j2π/N}, yₖ₍₋₁₎=0, n=N−1, N−2, . . . , 2, 1, 0, and k=0, 1, 2, . . . , N−1.
In general, the Goertzel algorithm depicted in FIG. 1 uses N iterations to compute each frequency of an input sequence of length N. The Goertzel algorithm may produce one frequency, which does not have to process the entire Fast Fourier Transform (FFT) to determine a frequency for a specific value k.

The Goertzel algorithm provides a means for efficient evaluation of individual terms of the discrete Fourier Transform (DFT), making it useful in various practical signal processing applications, such as the recognition of tones produced by the pushing of buttons on a telephone keypad. The algorithm was first described by Gerald Goertzel in 1958 in a paper entitled “An Algorithm for the Evaluation of Finite Trigonometric Series”, which was published in American Mathematical Monthly, vol. 65 (1): pp. 34-35, January 1958. The Goertzel algorithm may analyze one selectable frequency component from a discrete signal and may apply a single real-valued coefficient at each iteration, using real-valued arithmetic for real-valued input sequences. The simple structure of the Goertzel algorithm makes it well suited to small processors and embedded applications, though it is not so limited.

FIG. 2 depicts a block diagram 200 of the second order Goertzel algorithm. The second order Goertzel algorithm provides filtering according to the flow graph depicted in FIG. 2. The diagram 200 includes an input 202 to receive an input signal x(n). the input 202 is coupled to a convolution node 204(1), which includes a first input to receive the input 202, a second input to receive a feedback node 206, and an output coupled to an intermediate node 208. The diagram 200 further incudes a second convolution node 204(2), which includes a first input coupled to the intermediate node 208, a second input coupled to a feedforward node 212, and an output coupled to an output node 210.

The intermediate node 208 may be coupled to the node 212 through a first Z-transform. The node 212 may be coupled to a first input of a third convolution node 204(3). A second input of the third convolution node 204(3) may be coupled to a feedback node 214, which may be coupled to the node 212 through a second Z-transform. The third convolution node 204(3) may include an output coupled to the feedback node 206.

In an example involving complex-valued input sequences, the computational complexity of the first-order Goertzel algorithm includes 4N real multiplications and 4N real additions. In contrast, the second-order Goertzel algorithm depicted in FIG. 2 has a computational cost of 4N+2 real multiplications and 4N−2 real additions, which provides a reduction of almost a factor of two in the number of real multiplications as compared to the discrete Fourier transform equation.

Further, the first-order Goertzel algorithm produces a frequency for the specific value k. The second-order Goertzel algorithm may provide improved accuracy; however, more hardware is used and there may be more hardware delays as compared to the first-order Goertzel filter.

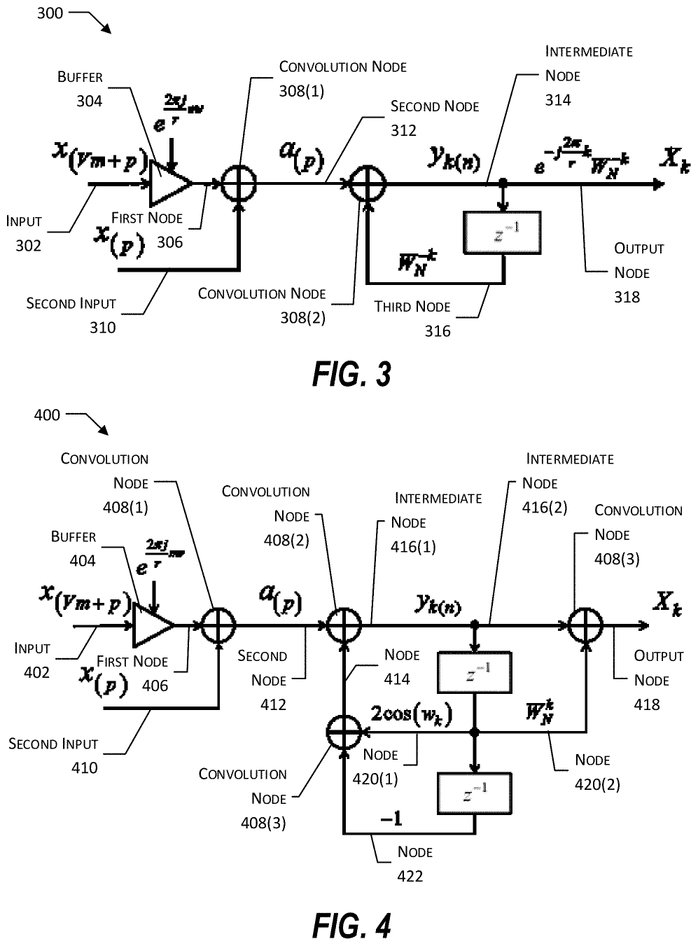

FIG. 3 depicts a block diagram of a radix-r first-order filter 300 according to some embodiments. The first-order filter 300 may include an input 302 to receive an input signal x_{(Vm+p)}. The filter 300 may include a buffer 304 to receive the input signal and a second signal and to provide an output to a first node 306. The filter 300 may include a first convolution node 308(1) including a first input coupled to the first node 306, a second input 310 to receive a second input signal x₍ₚ₎, and an output coupled to a second node 312 to provide an output signal a₍ₚ₎.

The filter 312 may include a second convolution node 308(2), which includes an input coupled to the second node 312, a second input coupled to a third node 316, and an output to provide an intermediate signal yₖ₍ₙ₎ to an intermediate node 318. The third node 316 may be coupled to the intermediate node 318 through a Z-transform. The filter 300 may further include an output node 320 to provide an output signal Xₖ.

FIG. 4 depicts a block diagram of a radix-r second-order filter 400 according to some embodiments. The filter 400 may include an input 402 to receive an input signal x_{(Vm+p)}. The filter 400 may include a buffer 404 to receive the input signal and a second signal and to provide an output to a first node 406. The filter 400 may further include a first convolution node 408(1) including a first input coupled to the first node, a second input 410 to receive a second signal x₍ₚ₎, and an output to provide a signal a₍ₚ₎ to a second node 412.

The filter 400 may include a second convolution node 408(2) including an input coupled to the second node 412, a second input coupled to a node 414, and an output to provide an output signal yₖ₍ₙ₎ to an intermediate node 416(1), which may be coupled to a second intermediate node 416(2). The filter 400 may also include a third convolution node including a first input coupled to the second intermediate node 416(2), a second input coupled to a node 420(2), and an output node 418 to provide an output signal Xₖ.

The node 420(2) is coupled to the first intermediate node 416 through a Z-transform. The node 414 is coupled to the intermediate node 416 through the z-transform, a node 420, a second z-transform and a node 422. The filter 400 includes a fourth convolution node 408 including a first input coupled to the node 420(1), a second input coupled to the node 422, and an output coupled to the node 414.

The second order filtering algorithm can be expressed according to the following equation:

$${y}_{k ( n )} = 2 cos ( \frac{2 π k}{N} ) {Y}_{k ( n - 1 )} - {y}_{k ( n - 2 )} + {x}_{( n )} , \qquad ( Equation 4 )$$

and the k^{th} frequency output may be expressed as follows:

Xₖ=y_{k(N-1)}+W_{N}^{k}y_{k(N-2)} ,(Equation 5)

where yₖ₍₋₂₎=yₖ₍₋₁₎=0.

The one iteration DIT FFT algorithm expressed as according to the following equation:

X_{(qV+v)}=Σₚ₌₀^{V-1} [symbol] Σₘ₌₀^{r-1}x_{(mV+p)} [symbol] , (Equation 6)

where [symbol] x [symbol] _{N} represents the operation x modulo N, v=0, 1 , . . . , V−1, q=0, 1, . . . , r−1, and V=N/r, where N is the number of bits, and r is the radix.

To compute a specific frequency X₍ₖ₎ for a given k, the values of q and v must be known in advance. And so, by adopting the following notation:

$$\{ \begin{matrix}0 \leq k < V & q = 0 and v = k \\ V \leq k < 2 V & q = 1 and v = k - V \\ ⋮ & \\ ( r - 1 ) V \leq k < N & q = ( r - 1 ) and v = k - ( r - 1 ) V\end{matrix} \qquad ( Equation 7 )$$

The second part of Equation 6 may be defined as follows:

$$\begin{matrix}{a}_{( p )} = {\sum }_{m = 0}^{r - 1} {x}_{( m V + p )} {w}_{N}^{{〚 mvV 〛}_{N}} \\ = {\sum }_{m = 0}^{r - 1} {x}_{( m V + p )} {e}^{- j \frac{2 π \frac{N}{r}}{N} mv} \\ = {\sum }_{m = 0}^{r - 1} {x}_{( m V + p )} {e}^{- j \frac{2 π}{r} mv} .\end{matrix} \qquad ( Equation 8 )$$

Therefore, Equation 6 can be expressed as follows:

Xₖ=Σₚ₌₀^{V-1}W_{N}^{pk}a₍ₚ₎ ,(Equation 9)

where k=qV+v, and

$${W}_{N}^{k} = {e}^{- j \frac{2 π k}{N}} = {e}^{- j \frac{2 π}{N} ( qV + v )} .$$

As a result, the radix-r first order JM-Filter could be derived according to the following equation:

yₖ₍ₚ₎=W_{N}^{-k}yₖ₍ₚ₋₁₎+a₍ₚ₎ ,(Equation 10)

Further, the k^{th} computed frequency may be determined according to the following equation:

$${X}_{k} = {e}^{- j \frac{2 π}{r} k} {W}_{N}^{- y} {y}_{k ( V - 1 )} . \qquad ( Equation 11 )$$

where yₖ₍₋₁₎=0 with p=0, 1, . . . , V−1.

The radix-r second-order JM-Filter may be expressed as follows:

yₖ₍ₚ₎=2 cos(2πk/N)yₖ₍ₚ₋₁₎−y_{k(p-2,)}+a₍ₚ₎ (Equation 12)

where yₖ₍₋₂₎=yₖ₍₋₁₎=0, and from which the k^{th} computed frequency may be expressed as follows:

$${X}_{k} = {e}^{- j \frac{2 π}{r} k} ( {W}_{N}^{k} {y}_{k ( V - 1 )} - {y}_{k ( V - 2 )} ) , \qquad ( Equation 13 )$$

The filtering operation for the first and second-order JM-Filter with the associated flow graphs is depicted in FIGS. 3 and 4, respectively.

By examining Equation 8, further reductions in terms of complexity could be achieved for the radix-2 case, since

$${e}^{- j \frac{2 π}{r} mv} = {e}^{- j π mv} = {( - 1 )}^{mv} . \qquad ( Equation 14 )$$

Based on Equation 14, we can rewrite Equation 8 as follows:

a₍ₚ₎=Σₘ₌₀^{r-1}x_{(Vm+p)}(−1)^{mv}=x₍ₚ₎+(−1)^{v}x_{(V+p)} .(Equation 15)

The first-order radix-2 Filter may be expressed as follows:

yₖ₍ₚ₎=W_{N}^{-k}yₖ₍ₚ₋₁₎+x₍ₚ₎+(−1)^{v}x_{(V+p)} (Equation 16)

and the k^{th} computed frequency is given by the following equation:

Xₖ=(−1)^{k}W_{N}^{-k}y_{k(V-1)} .(Equation 17)

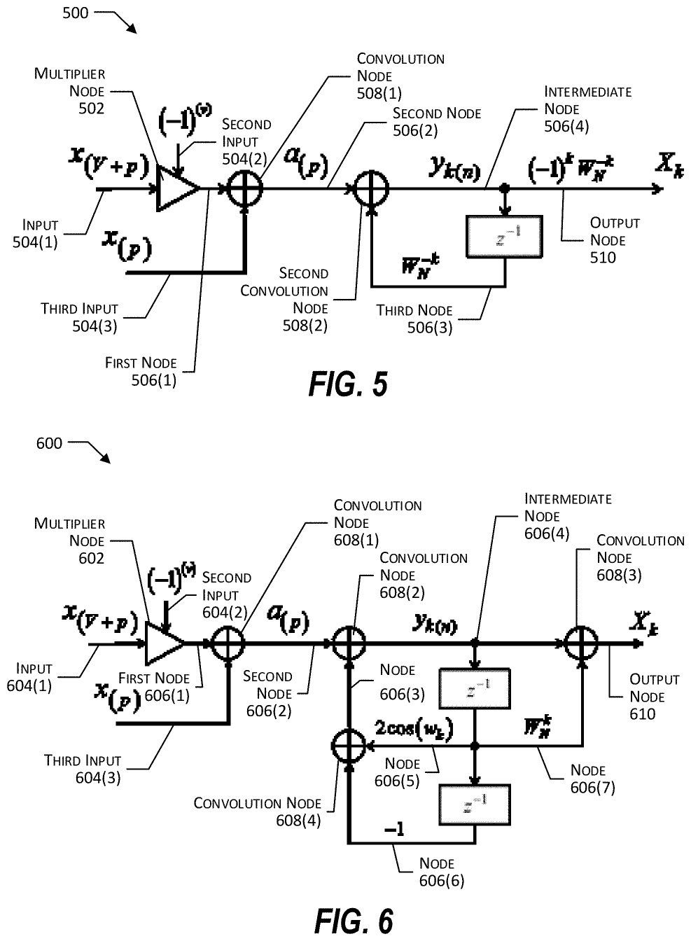

A signal graph of the radix-2 first order filter is described below with respect to FIG. 5.

FIG. 5 depicts a diagram of a radix-2, first-order filter 500, in accordance with certain embodiments of the present disclosure. The filter 500 may include a multiplier node 502 including a first input 504(1) to receive a signal, a second input 504(2) coupled to receive a twiddle factor, and an output coupled to a node 306(1). The filter 500 may include a convolution node 508(1) including a first input coupled to the node 506(1), a second input coupled to a third input 504(3), and an output to provide a signal a₍ₚ₎ to a second node 506(2). The filter 500 may further include a second convolution node 508(2) including an input coupled to the second node 506(2), a second input coupled to a third (feedback) node 506(3), and an output to provide a signal yₖ₍ₙ₎ coupled to a fourth (intermediate) node 506(4). The filter 500 may include a Z-transform coupled between the third (feedback) node 506(3) and the fourth (intermediate) node 506(4). The filter may further include an output node 510. The radix-2 first order filter can be understood mathematically from Equation 17 above from which the Kth computed frequency can be determined.

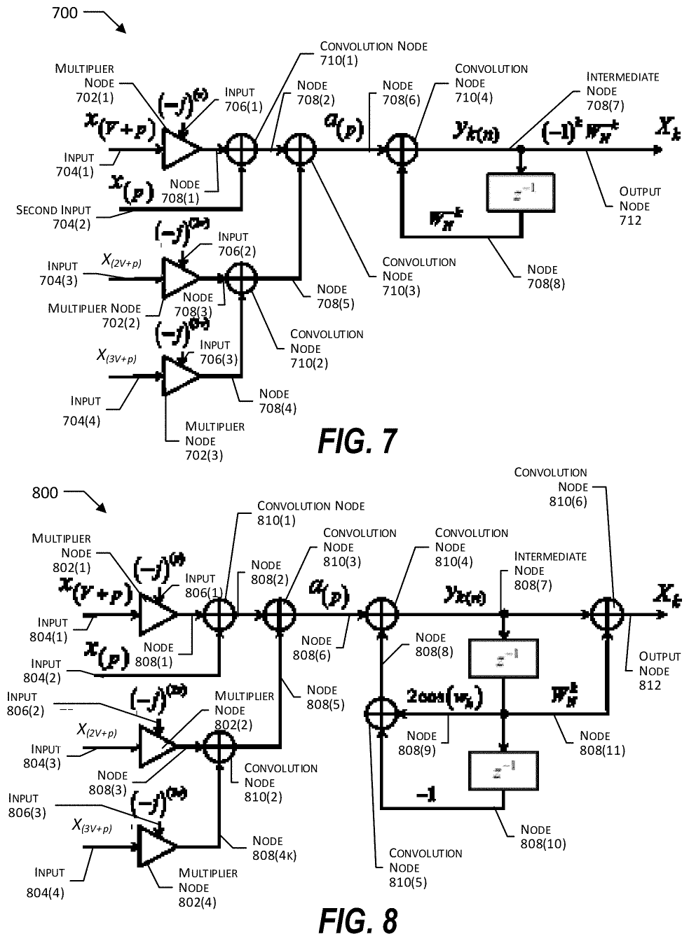

The radix-2 second-order filter may be described below with respect to FIG. 7. In particular, the radix-2 second-order filter may be understood according to the following equation:

yₖ₍ₚ₎=2 cos(2πk/N)yₖ₍ₚ₋₁₎−yₖ₍ₚ₋₂₎+a₍ₚ₎ ,(Equation 18)

where yₖ₍₋₂₎=yₖ₍₋₁₎=0. From Equation 18, the k^{th} computed frequency can be determined as follows:

Xₖ=(−1)^{k}(0.5 cos(2πk/N)y_{k(V-1)}+sin(2πk/N)−y_{k(V-2)}), (Equation 19)

FIG. 6 depicts a diagram of a radix-2 second-order filter 600, in accordance with certain embodiments of the present disclosure. The filter 600 may include a multiplier node 602 including a first input 604(1) to receive a signal, a second input 604(2) coupled to receive a twiddle factor, and an output coupled to a node 606(1). The filter 600 may include a convolution node 608(1) including a first input coupled to the node 606(1), a second input coupled to a third input 604(3), and an output to provide a signal a₍ₚ₎ to a second node 606(2). The filter 600 may further include a second convolution node 608(2) including an input coupled to the second node 606(2), a second input coupled to a third (feedback) node 606(3), and an output to provide a signal yₖ₍ₙ₎ coupled to a fourth (intermediate) node 606(4). The filter 600 may include a Z-transform coupled between the the fourth (intermediate) node 606(4) and a fifth node 606(5) to provide an output signal 2 cos(wₖ). The filter 600 may also include a second Z-transform coupled between the node 606(5) and a node 606(6) to provide a signal (−1). The filter 600 may also include a fourth convolution node 608(4) including a first input coupled to the node 606(6), a second input coupled to the node 606(5), and an output coupled to the node 606(3). The filter 600 may further include a third convolution node 608(3) including an input coupled to the intermediate node 606(4), a second input coupled to the node 606(7), and an output to provide an output signal Xₖ to an output node 610.

With the same reasoning as above, further reductions in terms of complexity for the radix-4 first and second-order filters could be achieved. For example, the twiddle factors may be simplified as follows:

$${e}^{- j \frac{2 π}{4} mv} = {e}^{- j \frac{π}{2} mv} = {( - j )}^{mv} . \qquad ( Equation 20 )$$

Therefore, based on Equation 20, Equation 8 can be rewritten as follows:

$$( Equation 21 )$$

$$\begin{matrix}{a}_{( p )} = {\sum }_{m = 0}^{r - 1} {{x}_{( Vm + p )} ( - j )}^{mv} \\ = {x}_{( p )} + {( - j )}^{v} {x}_{( V + p )} + {( - j )}^{2 v} {x}_{( 2 V + p )} + {( - j )}^{3 v} {x}_{( 3 V + p )}\end{matrix}$$

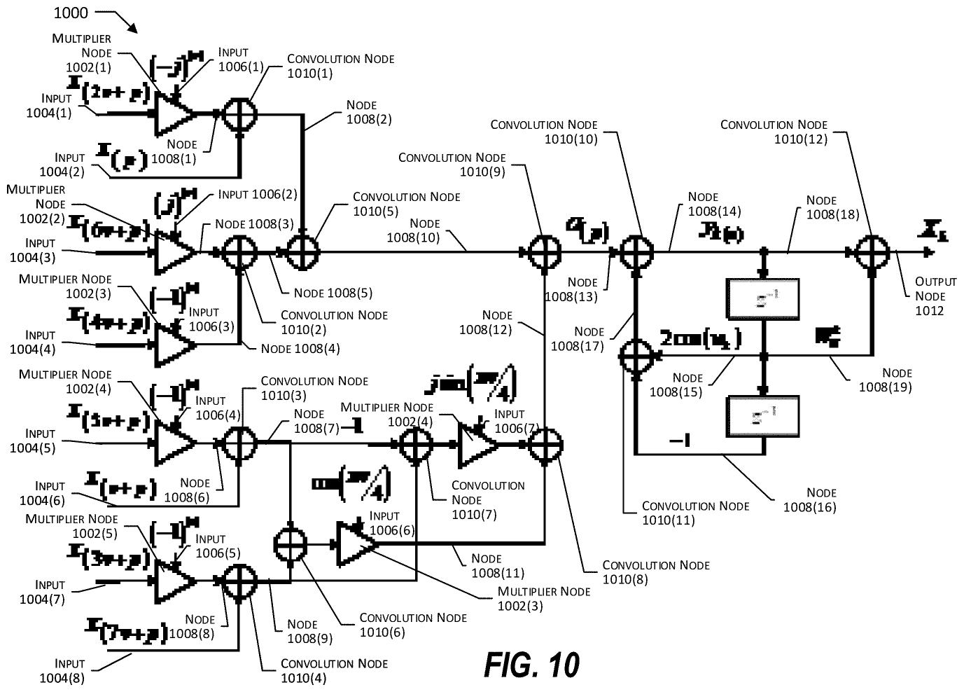

The radix-4 first order filter is described below with respect to FIG. 10 and can be understood according to the following equation:

yₖ₍ₚ₎=W_{N}^{-k}yₖ₍ₚ₋₁₎+a₍ₚ₎ ,(Equation 22)

where the k^{th} computed frequency is given according to the following equation:

Xₖ=(−j)^{k}W_{N}^{-k}y_{k(V-1)} .(Equation 23)

FIG. 7 depicts a diagram of a radix-4 first-order filter 700, in accordance with certain embodiments of the present disclosure. The filter 700 may include multiplier nodes702. A first multiplier node 702(1) may include a first input 704(1) to receive a first input signal x_{(V+p}), a second input 706(1) to receive a signal (−j)^{(v)}, and an output coupled to a node 708(1). A second multiplier node 702(2) may include an input 704(3) to receive a first input signal x_{(2V+p}), a second input 706(1) to receive a signal (−j)^{(2v)}, and an output coupled to a node 708(3). A third multiplier node 702(3) may include an input 704(4) to receive a first input signal x_{(3V+p)}, a second input 706(3) to receive a signal (−j)^{(3v}), and an output coupled to a node 708(4).

The filter 700 may include a first convolution node 710(1) including an input coupled to the node 708(1), a second input coupled to the input 704(2), and an output coupled to a node 708(2). The filter 700 may further include a convolution node 710(2) including an input coupled to the node 708(3), a second input coupled to the node 708(4), and an output coupled to a node 708(5). The filter 710 may include a third convolution node 710(3) including a first input coupled to the node 708(2), a second input coupled to a node 708(5), and an output to provide a signal a₍ₚ₎ to a node 708(6).

The filter 700 may also include a convolution node 710(4) including a first input coupled to the node 708(6), a second input coupled to a node 708(8), and an output to provide a signal yₖ₍ₙ₎ to an intermediate node 708(7). The node 708(8) may be coupled to the intermediate node 708(7) through a Z-transform. The filter 700 may further include an output node 712 coupled to the intermediate node 708(7).

The radix-4 second-order filter can be understood according to the following equation:

yₖ₍ₚ₎=2 cos(2πk/N)y₍ₚ₋₁₎−yₖ₍ₚ₋₂₎+a₍ₚ₎ (Equation 24)

where yₖ₍₋₂₎=yₖ₍₋₁₎=0. The k^{th} computed frequency can be determined according to the following equation:

Xₖ=(−j)^{k}(0.5 cos(2πk/N)y_{k(V-1)}−y_{k(V-2)}+j sin(2πk/N)y_{k(V-1)} (Equation 25)

with k=0, 1, . . . , N−1 to compute all frequencies.

FIG. 8 depicts a diagram of a radix-4 second-order filter 800, in accordance with certain embodiments of the present disclosure. The filter 800 may include a multiplier node 802(1) including a first input 804(1) to receive an input signal X_{(V+p)}, a second input to receive a twiddle factor (−j)^{(v)}, and an output coupled to a node 808(1). The filter 800 may include a multiplier node 802(2) including an input 804(3) to receive an input signal X_{(2V+p)}, an input 806(2) to receive a twiddle factor (−j)^{(2v)}, and an output coupled to a node 808(3). The filter 800 may further include a multiplier node 802(3) including an input 804(4) to receive an input signal X_{(3V+p)}, an input 806(3) to receive a twiddle factor (−j)^{(3v)}, and an output coupled to a node 808(4).

The filter 800 may include a convolution node 810(2) including an input coupled to the node 808(3), an input coupled to the node 808(4), and an output coupled to a node 808(5). The filter 800 may further include a convolution node 810(3) including an input coupled to the node 808(2), an input coupled to the node 808(5), and an output to provide a signal a(ₚ₎ to a node 808(6). The filter 800 may further include a convolution node 810(4) including an input coupled to a node 808(6), an input coupled to a node 808(8), and an output to provide a signal yk(n) to an intermediate node 808(7).

The filter 800 may include a node 808(9) coupled to the intermediate node 808(7) through a Z-transform. The filter 800 may further include a node 808(10) coupled to the node 808(9) through a Z-transform. The filter 800 may also include a convolution node 810(5) including an input coupled to the node 808(9), an input coupled to the node 808(10), and an output coupled to the node 808(8). The filter 800 may further include a node 808(11) coupled to the intermediate node 808(7) through the Z-transform. The filter 800 may also include a convolution node 810(6) including an input coupled to the intermediate node 808(7), an input coupled to the node 808(11), and an output to provide a signal Xₖ to an output node 812.

The computational complexity of the first and second order radix-4 filter may include, respectively:

N real multiplications and 5N/2 real additions, (Equation 26)

N/2+2 real multiplications and 5N/2−2 real additions, (Equation 27)

which provides a reduction by a factor of 4 in the computational cost of the multiplications where Nₐ_{₍ₚ₎}^{MULT}=0Nₐ_{₍ₚ₎}^{MULT}=0.

By examining Equation 8, further reductions in terms of complexity could be achieved for the radix-8 case since the twiddle factors can be simplified according to the following equivalency:

$${e}^{- j \frac{2 π}{8} mv} = {e}^{- j \frac{π}{4} mv} , \qquad ( Equation 28 )$$

Therefore, based on Equation 28, Equation 8 can be rewritten as presented equation 29, such that the radix-8 first order filter can be expressed according to the following equation:

yₖ₍ₚ₎=w_{N}^{-k}yₖ₍ₚ₋₁₎+a₍ₚ₎ ,(Equation 29)

and the k^{th} computed frequency can be determined according to the following equation:

$${X}_{k} = {e}^{( - j \frac{π}{4} k )} {w}_{N}^{- k} {y}_{k ( V - 1 )} . \qquad ( Equation 30 )$$

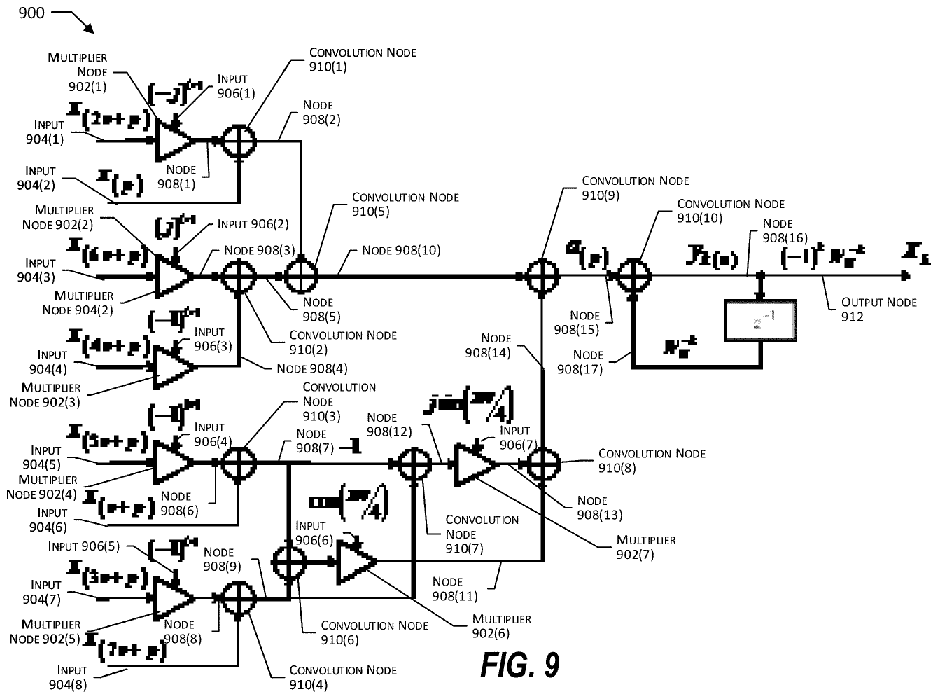

FIG. 9 depicts a radix-8 first-order filter 900 according to some embodiments. The filter 900 may include multipliers 902. The multiplier 902(1) may include an input 904(1) to receive an input signal x₍₂ᵥ₊ₚ₎, an input 906(1) to receive a signal −j^{v}, and an output coupled to a node 908(1). The filter 900 may further include a convolution node 910(1) including a first input coupled to the node 908(1), an input 904(2) to receive a signal x₍ₚ₎, and an output coupled to a node 908(2).

The filter 900 may include a multiplier 902(2) including an input 904(3) to receive an input signal x₍₆ᵥ₊ₚ₎, an input 906(2) to receive a signal j^{v}, and an output coupled to a node 908(3). The filter 900 may also include a multiplier 902(3) including an input 904(4) to receive an input signal x₍₄ᵥ₊ₚ₎, an input 906(3) to receive a signal −1^{v}, and an output coupled to a node 908(4). The filter 900 may further include a convolution node 910(2) including an input coupled to the node 908(3), an input coupled to the node 908(4), and an output coupled to a node 908(5).

The filter 900 may include a multiplier 902(4) including an input 904(5) to receive an input signal x₍₅ᵥ₊ₚ₎, an input 906(6) to receive a signal −1^{v}, and an output coupled to a node 908(6). The filter 900 may further include a convolution node 910(3) including an input coupled to the node 908(6), an input 904(6) to receive a signal X₍ᵥ₊ₚ₎, and an output coupled to a node 908(7).

The filter 900 may further include a multiplier 902(5) including an input 904(7) to receive an input signal x₍₃ᵥ₊ₚ₎, an input 906(5) to receive a signal −1^{v}, and an output coupled to a node 908(8). The filter 900 may further include a convolution node 910(4) including an input coupled to the node 908(8), an input 904(8) to receive an input signal x₍₇ᵥ₊ₚ₎, and an output coupled to a node 908(9).

The filter 900 may include a convolution node 910(5) including an input coupled to the node 908(2), an input coupled to the node 908(5), and an output coupled to an intermediate node 908(10). The filter 900 may also include a convolution node 910(6) including an input coupled to the node 908(7), an input coupled to the node 908(9), and an output coupled to an input of a multiplier 902(6). The multiplier 902(6) includes a second input 906(6) to receive an input signal

$$cos ( \frac{π v}{4} ) ,$$

and an output coupled to a node 908(11). The filter 900 may further include a convolution node 910(7) including an input coupled to the node 908(7), a second input coupled to the node 908(9), and an output coupled to a node 908(12). The filter 900 may further include a multiplier 902(7) including an input coupled to the node 908(12), an input 906(7) to receive a signal

$$j sin ( \frac{π v}{4} ) ,$$

and an output coupled to a node 908(13). The filter 900 may also include a convolution node 910(8) including an input coupled to a node 908(10), an input coupled to a node 908(14), and an output to provide a signal a₍ₚ₎ to a node 908(15).

The filter 900 may include a convolution node 910(10) including an input coupled to the node 908(15), an input coupled to a node 908(17), and an output coupled to an intermediate node 908(16). The node 908(17) is coupled to the intermediate node 908(16) through a Z-transform. The filter 900 may further include an output node 912 to provide an output signal Xₖ.

The radix-8 second-order JM-Filter described below with respect to FIG. 10 may be understood according to the following equation:

$${a}_{( p )} = {x}_{( p )} + {( - j )}^{v} {x}_{( 2 V + p )} + {( - 1 )}^{v} {x}_{( 4 V + p )} + {( j )}^{v} {x}_{( 6 V + p )} + {( \frac{\sqrt{2}}{2} )}^{v} [ {( 1 - j )}^{v} ( {x}_{( V + p )} + {( - 1 )}^{v} {x}_{( 5 V + p )} ) + {( - 1 )}^{v} {( 1 + j )}^{v} ( {x}_{( 3 V + p )} + {( - 1 )}^{v} {x}_{( 7 V + p )} ) ] \qquad ( Equation 31 )$$

The intermediate signal can be understood according to the following equation:

yₖ₍ₚ₎=2 cos(2πk/N)yₖ₍ₚ₋₁₎−yₖ₍ₚ₋₂₎+a₍ₚ₎ ,(Equation 32)

where yₖ₍₋₂₎=yₖ₍₋₁₎=0. The k^{th} computed frequency can be determined according to the following equation:

$${X}_{k} = {e}^{( - j \frac{π}{4} k )} [ ( 0.5 cos ( 2 π k / N ) + j sin ( 2 π k / N ) + j sin ( 2 π k / N ) ) {y}_{k ( V - 1 )} - {y}_{k ( V - 2 )} ] \qquad ( Equation 33 )$$

with k=0, 1, . . . , N−1.

FIG. 10 depicts a radix-8 second-order filter 1000 according to some embodiments. The filter 1000 may include multipliers 1002. The multiplier 1002(1) may include an input 1004(1) to receive an input signal x₍₂ᵥ₊ₚ₎, an input 1006(1) to receive a signal −j^{v}, and an output coupled to a node 1008(1). The filter 1000 may further include a convolution node 1010(1) including a first input coupled to the node 1008(1), an input 1004(2) to receive a signal x₍ₚ₎, and an output coupled to a node 1008(2).

The filter 1000 may include a multiplier 1002(2) including an input 1004(3) to receive an input signal x₍₆ᵥ₊ₚ), an input 906(2) to receive a signal j^{v}, and an output coupled to a node 1008(3). The filter 1000 may also include a multiplier 1002(3) including an input 1004(4) to receive an input signal x₍₄ᵥ₊ₚ₎, an input 1006(3) to receive a signal −1^{v}, and an output coupled to a node 1008(4). The filter 1000 may further include a convolution node 1010(2) including an input coupled to the node 1008(3), an input coupled to the node 1008(4), and an output coupled to a node 1008(5).

The filter 1000 may include a multiplier 1002(4) including an input 1004(5) to receive an input signal x₍₅ᵥ₊ₚ₎, an input 1006(4) to receive a signal (−1)^{v}, and an output coupled to a node 1008(6). The filter 1000 may further include a convolution node 1010(3) including an input coupled to the node 1008(6), an input 1004(6) to receive a signal X₍ᵥ₊ₚ₎, and an output coupled to a node 1008(7).

The filter 1000 may further include a multiplier 1002(5) including an input 1004(7) to receive an input signal x₍₃ᵥ₊ₚ₎, an input 1006(5) to receive a signal (−1)^{v}, and an output coupled to a node 1008(8). The filter 1000 may further include a convolution node 1010(4) including an input coupled to the node 1008(8), an input 1004(8) to receive an input signal x₍₇ᵥ₊ₚ₎, and an output coupled to a node 1008(9).

The filter 1000 may include a convolution node 1010(5) including an input coupled to the node 1008(2), an input coupled to the node 1008(5), and an output coupled to an input of a multiplier node 1002(3). The multiplier node 1002(3) may include a second input 1006(6) to receive an input signal

$$cos ( \frac{π v}{4} ) ,$$

and an output coupled to a node 1008(11). The filter 1000 may also include a convolution node 1010(7) including an input coupled to the node 1008(7), an input coupled to the node 1008(9), and an output coupled to an input of a multiplier 1002(4). The multiplier 1002(4) includes a second input 1006(7) to a signal

$$j sin ( \frac{π v}{4} ) ,$$

and an output coupled to an input of a convolution node 1010(8). The convolution node 1010(8) may include a second input coupled to a node 1008(11), and an output coupled to a node 1008(12). The filter 1000 may also include a convolution node 1010(9) including an input coupled to a node 1008(10) and an output to provide a signal a₍ₚ₎ to a node 1008(13).

The filter 1000 may include a convolution node 1010(10) including an input coupled to the node 1008(13), an input coupled to a node 1008(17), and an output coupled to an intermediate node 1008(14). The filter 1000 may include a Z-transform between the intermediate node 1008(14) and a node 1008(15). The filter may include a second Z-transform between the node 1008(15) and a node 1008(16). The filter 1000 may include a convolution node 1010(11) including an input coupled to the node 1008(15), an input coupled to the node 1008(16), and an output coupled to the node 1008(17). The filter 1000 further includes a node 1008(19) coupled to the intermediate node 1008(14) through a Z-transform. The filter 1000 may further include a convolution node 1010(12) including an input coupled to a node 1008(18) that is coupled to the intermediate node 1008(14), a second input coupled to the node 1008(19), and an output to provide a signal Xₖ to an output node 1012.

The performance evaluation results are based on real additions (⊕) and real multiplication (\textcircled{×}) for the execution of the Goertzel filters of FIGS. 1 and 2 and the filters of FIGS. 3-9 for different radix-r. In term of accuracy, the algorithms are executed in fixed-point that is defined by the Signal to Quantization Noise Ratio (SQNR).

In general, the computational complexity of the first order Goertzel algorithm in the case of complex-valued input sequences is

4N real \textcircled{×} and 4N real ⊕, (Equation 34)

and (as can be seen in FIG. 2), the computational cost of the second-order Goertzel algorithm is

2N+2 real \textcircled{×} and 4N−2 real ⊕, (Equation 35)

which gives a reduction of almost a factor of two in the number of real multiplications. If the data is real-valued, this cost is almost halved again.

In general, for the radix-r case, the computational complexity of the first and second order radix-r filter of FIGS. 3-10 are respectively

$$\begin{matrix}4 N / r + {N}_{{a}_{( p )}}^{MULT} real ⊗ and 4 N / r + {N}_{{a}_{( p )}}^{ADD} real ⊕ , & ( Equation 36 ) \\ 2 N / r + 2 + {N}_{{a}_{( p )}}^{MULT} real ⊗ and 4 N / r - 2 + {N}_{{a}_{( p )}}^{ADD} real ⊕ , & ( Equation 37 )\end{matrix}$$

where

$${N}_{{a}_{( p )}}^{ADD} and {N}_{{a}_{( p )}}^{MULT} ,$$

are the total number of the required operations required to compute a₍ₚ₎. As a result, the computational complexity of the first and second order radix-2 filters of FIGS. 3-9, including

$${N}_{{a}_{( p )}}^{MULT} and {N}_{{a}_{( p )}}^{ADD} ,$$

is respectively:

2N real \textcircled{×} and 3N real ⊕, (Equation 38)

N+2 real \textcircled{×} and 3N−2 real ⊕, (Equation 39)

which provides a reduction in the multiplications' computational cost by a factor of 2, where

$${N}_{{a}_{( p )}}^{MULT} = 0 ,$$

The filter uses 3N real additions compared to 4N real additions needed by Goertzel algorithm as shown in Table I.

Further, the computational complexity of the first and second order radix-4 Filter of FIGS. 7 and 8 is respectively:

N real \textcircled{×} and 5N/2 real ⊕, (Equation 40)

N/2+2 real \textcircled{×} and 5N/2−2 real ⊕, (Equation 41)

which provides a reduction in the multiplications' computational cost by a factor of 4, where

$${N}_{{a}_{( p )}}^{MULT} = 0 ,$$

and we need 5N/2 real additions compared to 4N−2 real additions required for Goertzel algorithm.

Based on FIGS. 9 and 10, the computational complexity of the first and second order radix-8 JM-Filter is respectively:

N real \textcircled{×} and 13N/8 real ⊕, (Equation 42)

3N/4+2 real \textcircled{×} and 13N/8−2 real ⊕, (Equation 43)

where

$${N}_{{a}_{( p )}}^{MULT} = \frac{N}{2} and where {N}_{{a}_{( p )}}^{ADD} = \frac{9 N}{8} .$$

The Table I summarize the complexity operations for the proposed JM Filter radix-2/4/8/r and the cited algorithms.

TABLE 1
Computational complexity in terms of real arithmetic operations for the first and
second order Goertzel algorithm and other Fourier Transform Algorithms compared to
the first and second order filters (radix-2, 4, and 8) of FIGs. 3-10 for a complex value
sequence signal of length N.

| | First Order | | Second Order | |
|---|---|---|---|---|
| Methods | ⊗ | ⊕ | ⊗ | ⊕ |
| Goertzel | 4N² | 4N² | 2N(N + 3) | 4N(N + 2) |
| L.D. Van, and C.C. | — | — | 2N(N + 1) | 4N(N + 1) |
| Yang Recursive | | | | |
| DFT/IDFT | | | | |
| L.D. Van and C.T. | — | — | 2N(N + 3) | 4N(N + 2) |
| Lin, et al. Recurive | | | | |
| DFT/IDFT | | | | |
| Meher, et al. | — | — | N²/2 − 8 | N² + 9.5N − 22 |
| Systolization of | | | | |
| DFT | | | | |
| Lai, et al., | — | — | (N + 1)(N − 2) | N(2N + 7) − 2 |
| Recursive | | | | |
| DFT/IDFT | | | | |
| Shin-Shi, Recursive | — | — | 2N(N + 1) | 4N × (N + 1) |
| DFT | | | | |
| JM-Filter radix-2 | 2N² | 3N² | N(N + 2) | N(3N − 2) |
| JM-Filter radix-4 | N² | 5N²/2 | N(N/2 + 2) | N(5N/2 − 2) |
| JM-Filter radix-8 | N² | 13N²/8 | N(3N/4 + 2) | N(13N/8 − 2) |
| JM-Filter radix-r | $N ( \frac{4 N}{r} + {N}_{{a}_{( p )}}^{MULT} )$ | $N ( \frac{4 N}{r} + {N}_{{a}_{( p )}}^{ADD} )$ | $N ( \frac{2 N}{r} + {N}_{{a}_{( p )}}^{MULT} + 2 )$ | $N ( \frac{4 N}{r} + {N}_{{a}_{( p )}}^{ADD} - 2 )$ |

Table 2 summarizes their complexity to produce a specific frequency. In these tables, the parallel multiplication/addition over r-parallel filter is counted as 1.

TABLE 2
Computational complexity in terms of real arithmetic operations
for the first and second order Goertzel algorithm and the cited
RDFT compared to the proposed first and second order JM-Filter
(radix-2, 4 and 8) for a complex valued sequence signal of
length N in order to produce a specific frequency.

| | First Order | | Second Order | |
|---|---|---|---|---|
| Methods | ⊗ | ⊕ | ⊗ | ⊕ |
| Goertzel [3] | 4N | 4N | 2(N + 3) | 4(N + 2) |
| L. D. Van, and C. C. | — | — | 2(N + 1) | 4(N + 1) |
| Yang Recursive | | | | |
| DFT/IDFT | | | | |
| L. D. Van and C. T. | — | — | 2(N + 3) | 4(N + 2) |
| Lin, et al. Recurive | | | | |
| DFT/IDFT | | | | |
| Meher, et al. | — | — | N/2 − 8 | N − 12.5 |
| Systolization of | | | | |
| DFT | | | | |
| Lai, et al., | — | — | (N − 1) | (2N + 5) |
| Recursive | | | | |
| DFT/IDFT | | | | |
| Shin-Shi, Recursive | — | — | 2(N + 1) | 4 × (N + 1) |
| DFT | | | | |
| JM-Filter radix-2 | 2N | 3N | (N + 2) | (3N − 2)/2 |
| Parallel JM-Filter | N | 3N/2 | (N + 2)/2 | (3N − 2) |
| radix-2 | | | | |

Given that the time delay for real addition (TA) is 4 times less than real multiplication (TM), therefore, Table III summarizes the critical path delay based on TM for each filter to produce a specific frequency.

TABLE 3
This table summarizes the critical path delay based on TM for each filter to
produce a specific frequency.

| | First Order | Second Order |
|---|---|---|
| Methods | Critical Path Delay | Critical Path Delay |
| Goertzel [3] | 5N T_{M} | (9N + 14)/4 T_{M} |
| L.D. Van, and C.C. | — | 3(N + 1)T_{M} |
| Yang Recursive | | |
| DFT/IDFT | | |
| L.D. Van and C.T. | — | 2N + 8 T_{M} |
| Lin, et al. Recurive | | |
| DFT/IDFT | | |
| Meher, et al. | — | (3N − 44)/32 T_{M} |
| Systolization of | | |
| DFT | | |
| Lai, et al., | — | (6N + 1)/4 T_{M} |
| Recursive | | |
| DFT/IDFT | | |
| Shin-Shi, Recursive | — | 3(N + 1)T_{M} |
| DFT | | |
| JM-Filter radix-2 | 11N/4 T_{M} | (11N + 14)/8 T_{M} |
| Parallel JM-Filter | 11N/8 T_{M} | (11N + 14)/16 T_{M} |
| radix-2 | | |
| JM-Filter radix-4 | 13N/8 T_{M} | (9N + 12)/8 T_{M} |
| Parallel JM-Filter | 13N/32 T_{M} | (9N + 12)/32 T_{M} |
| radix-4 | | |
| JM-Filter radix-8 | 45N/32 T_{M} | 37N/8 T_{M} |
| Parallel JM-Filter | 45N/256 T_{M} | 37N/64 T_{M} |
| radix-8 | | |
| JM-Filter radix-r | $( \frac{5 N}{r} + 2 \times {N}_{{a}_{( p )}}^{MULT} ) \times {T}_{M}$ | $( \frac{3 N}{r} + 2 \times {N}_{{a}_{( p )}}^{MULT} + 1.5 ) \times {T}_{M}$ |
| Parallel JM-Filter radix-r | $( \frac{5 N}{{r}^{2}} + 2 \times {N}_{{a}_{( p )}}^{MULT} ) \times {T}_{M}$ | $( \frac{3 N}{{r}^{2}} + 2 \times {N}_{{a}_{( p )}}^{MULT} + 1.5 ) \times {T}_{M}$ |

In digital processing, signal-to-quantization noise ratio, often written SQNR, represents a measure of signal strength relative to background noise. The ratio is usually measured in decibels (dB). When the ratio is higher, the background noise becomes less obtrusive. Two major concerns about the computation of the Goertzel's algorithm include the computation speed and the high SQNR. The fixed-point implementation may generate noise sources due to the bit representation in hardware implementation, which noise sources may propagate through the system and which can impact the overall system accuracy. The SNQR can be determined according to the following equation:

$$SQNR = 10 {log}_{10} ( \frac{‖ \{ x \} ‖}{‖ \{ x \} - \{ {\hat{x}}_{Q} \} ‖} ) dB \qquad ( Equation 44 )$$

where ∥x∥ define the norm-L₂ function of the signal x, x and x_{Q} represent the signal x in floating and fixed-point respectively. The norm is calculated on the complex valued signal sequence of length N measured in decibels (dB). The higher the ratio, the less obtrusive the background noise is. Two major concerns in the computation of the Goertzel algorithm are the speed and high SQNR. The fixed-point implementation generates noise sources due to the bit representation in hardware implementation that propagate through the system that can modifies the overall system accuracy.

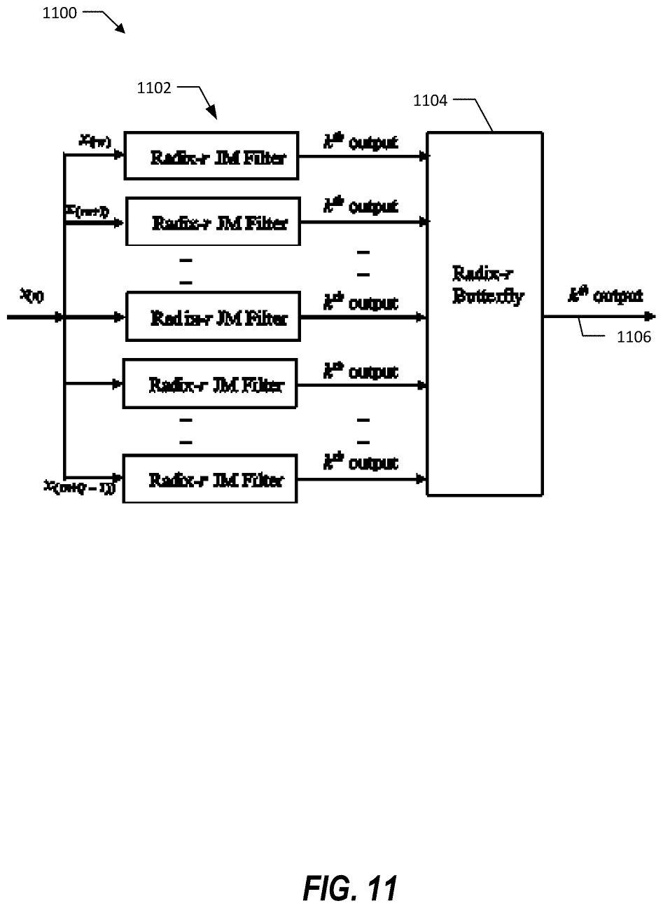

FIG. 11 depicts a parallel implementation 1100 of the radix-r first and second order filter to detect a specific frequency in one-dimension according to some embodiments. The parallel implementation 1100 depicts a plurality radix-r JM filters 1102 in parallel, each of which produces a Kth output, which are provided to a radix-r butterfly 1104, that provides the kth output 1106. It should be appreciated that the implementation 1100 may be used to determine a particular frequency.

The size of the parallelization is arbitrary, and may be selected based on the determined radix. In this implementation, r-filters 1102 are provided.

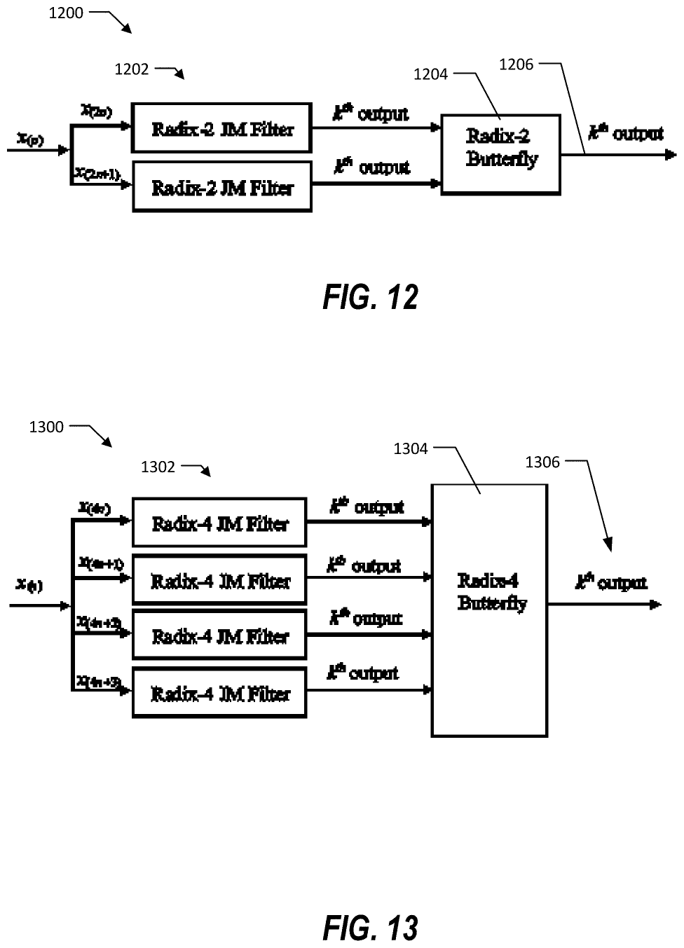

FIG. 12 depicts a parallel implementation 1200 of the radix-2 first and second order filter to detect a specific frequency in one-dimension according to some embodiments. In this implementation 1200, two radix-2 JM filters 1202 are provided, which provide two kth outputs to a radix-2 butterfly 1204, which produces a kth output 1206.

FIG. 13 depicts a parallel implementation 1300 of the radix-4 first and second order filter to detect a specific frequency in one-dimension according to some embodiments. In this implementation 1300, four radix-4 JM filters 1302 are provided, which provide four kth outputs to a radix-4 butterfly 1304, which produces a kth output 1306.

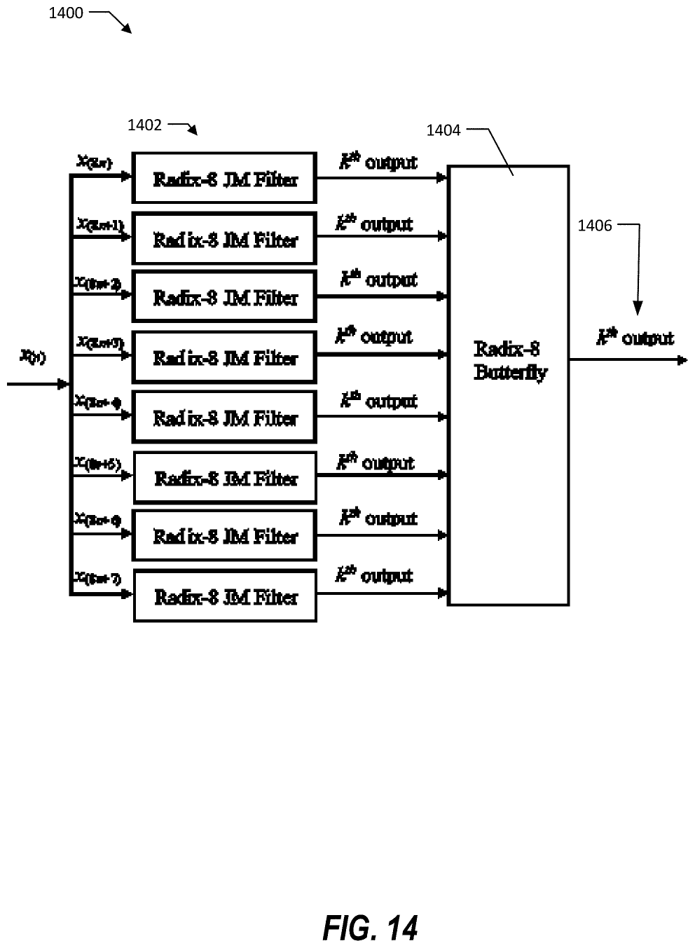

FIG. 14 depicts a parallel implementation 1400 of the radix-8 first and second order filter to detect a specific frequency in one-dimension according to some embodiments. In this implementation 1400, eight radix-8 JM filters 1402 are provided, which provide eight kth outputs to a radix-8 butterfly 1404, which produces a kth output 1406.

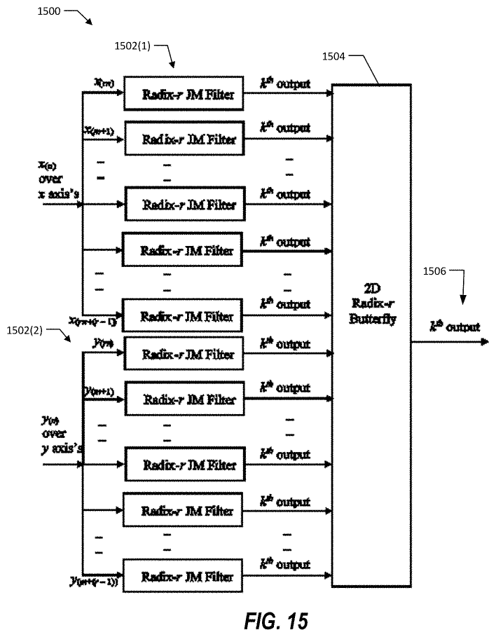

FIG. 15 depicts a parallel implementation 1500 of the radix-r first and second order filter to detect a specific frequency in two-dimensional space according to some embodiments. In this implementation 1500, two parallel radix-r JM filter groups 1502(1) and 1502(2) are provided to receive x and y inputs, respectively. The parallel radix-r JM filter groups 1502, which provide r kth outputs to a radix-r butterfly 1504, which produces a kth output 1506, representing the frequency in two-dimensional space.

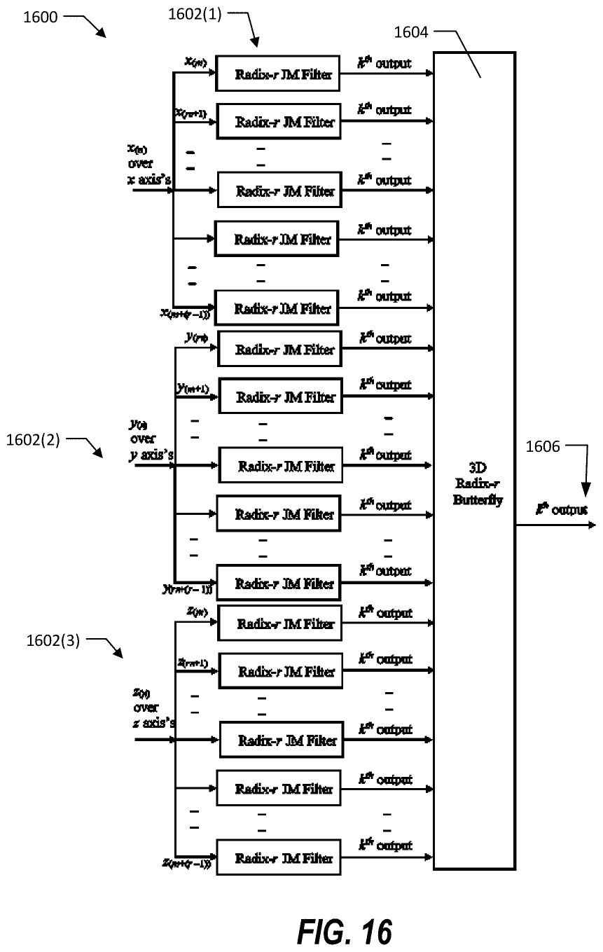

FIG. 16 depicts a parallel implementation 1600 of the radix-r first and second order filter to detect a specific frequency in three-dimensional space according to some embodiments. In this implementation 1600, three parallel radix-r JM filter groups 1602(1), 1602(2), and 1602(3) are provided to receive x, y, and z inputs, respectively. The parallel radix-r JM filter groups 1602, which provide r kth outputs to a radix-r butterfly 1604, which produces a kth output 1606, representing the frequency in three-dimensional space.

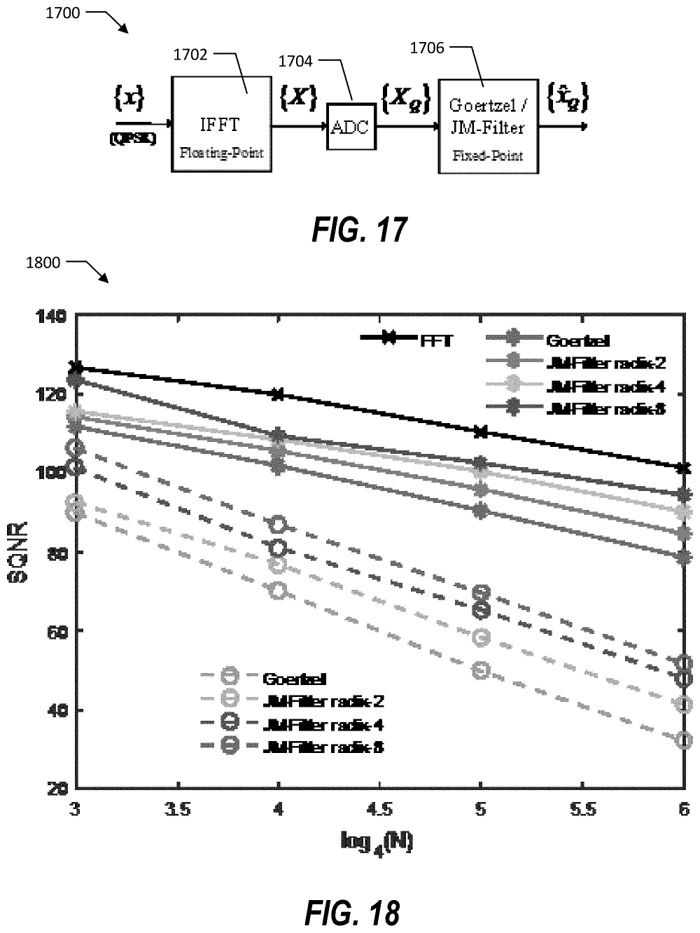

FIG. 17 depicts a block diagram 1700 of a fixed-point simulation with Quadrature Phase Shift Keying (QPSK) according to some embodiments. The diagram 1700 includes an inverse fast Fourier Transform (IFFT) floating point block 1702 to receive a QPSK signal and to produce an output X, which is provided to an analog-to-digital converter (ADC) 1704. The ADC 1704 produces a digital output X_{Q} that is provided to the filter 1706 (which may be a Goertzel/JM-Filter (fixed point)) to produce an output signal.

The first order Goertzel algorithm performs better than the second order in fixed-point implementation due background noise. The model illustrated in FIG. 17 represents the simplified transmitter-receiver commonly used in orthogonal frequency-division multiplexing (OFDM) communication systems with a quadrature phase-shift keying (QPSK) modulation. The first block 1702 represents the inverse FFT (IFFT) at the transmitter. The ADC 1704 follows and produces a finite Q-bit word length sent to the filter 1706 to reconstruct the input fixed-point signal. Several fixed-point simulations were conducted to compute the SQNR in term of the input/output data (called variable data) bit's word-length (bit width) and the twiddle factor (called coefficient). The SQNRs' simulations, are calculated based on this equation, and are shown in FIG. 18.

In the following discussion, the implementation of radix-r filters according to the present disclosure can be compared to a conventional Goertzel implementation. In the comparison, the filters are compared with respect to their processing of complex valued input data that has been quantized to 16/24 bits width and coefficient multiplier that has been quantized to 16 bits width in order to reduce the implementation cost.

FIG. 18 depicts a graph 1800 of Signal-to-Quantization-Noise Ratio (SQNR) versus a logarithm of the number of iterations for first and second order filters according to some embodiments. The graph 18 compares a first-order radix-2/4/8 and a first-order Goertzel approach on data and twiddle factors of 16 bits width where the scaling factor is 1/N, in accordance with certain embodiments of the present disclosure. The graph 1800 also includes the second order radix 2/4/8 and Goertzel approaches (shown in dashed lines).

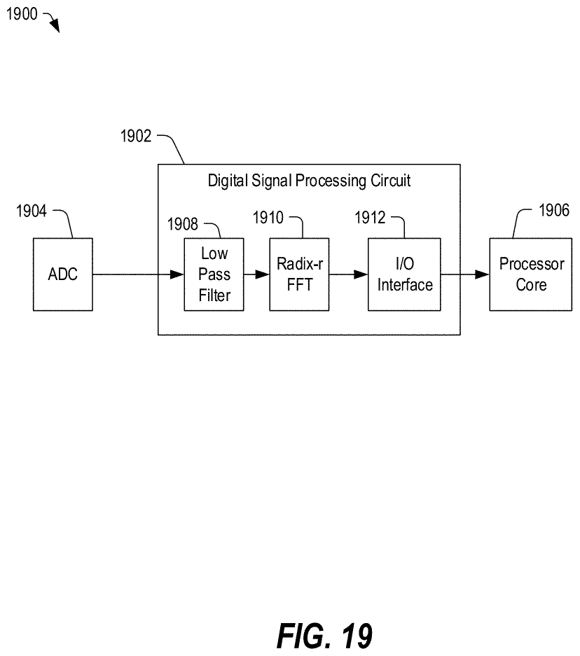

FIG. 19 depicts a block diagram of a system 1900 including a radix-r FFT circuit, in accordance with certain embodiments of the present disclosure. The system 1900 can include a digital signal processing circuit 1902 including an input configured to receive a digital signal from an analog-to-digital converter (ADC) 1904 and an output, which may be provided to a processor core 1906 or to another circuit. The digital signal processing circuit 1902 may include a low pass filter 1908 including an input coupled to the ADC 1904 and including an output coupled to a radix-r FFT 1910. The radix-r FFT 1910 may implement the FFT algorithm described above with respect to FIGS. 3-16. Further, the radix-r FFT 1910 may include an output coupled to an input/output (I/O) interface 1912, which may be coupled to the output.

It should be understood that the DSP circuit 1902 of FIG. 19 is provided for illustrative purposes only and is not intended to be limiting. Further, the radix-r FFT 1910 may include any of the implementations of FIGS. 3-16 and can provide a significant computational advantage as compared to conventional FFT implementations, in terms of the number of processor cycles. Moreover, it should be understood that the FFT described above with respect to the various equations and implementations of FIGS. 3-16 may be implemented in a variety of different contexts and circuits. In some instances, the methods may be implemented as software that can be executed by a processor (either as processor-level instructions or within a user-level application, such as a communications application, a gaming application, or another application).

In general, the algorithm disclosed herein provides a technique for determining specific frequencies within a signal, such as a frequency modulated carrier signal, that is computationally more efficient than a standard Goertzel implementation. Moreover, the technique can be used in a variety of contexts, including single tone detection, spectrum analysis, dual-tone multi-frequency (DTMF) for telecommunications systems, other digital signal processing applications, or any combination thereof. Further, embodiments of the present disclosure describe an efficient algorithm that can implemented by a digital signal processing circuit to compute a specific frequency while providing a significant reduction in the multiplication computational load by a factor of r and a significant gain in SQNR as compared to a conventional Goertzel algorithm.

Although the present invention has been described with reference to preferred embodiments, workers skilled in the art will recognize that changes may be made in form and detail without departing from the scope of the invention.

What is claimed is:

1. A circuit comprising:
an input configured to receive a signal; and
a radix-r fast Fourier transform (FFT) processing element coupled to the input and configured to subdivide data of size N into r equal sub-domains of size N/r−1 to determine specific frequencies.

2. The circuit of claim 1, wherein the radix-r FFT processing element comprises:
r parallel complex multipliers, each of the r parallel complex multipliers including a first input configured to receive one of the r equal sub-domains of the data, a second input configured to receive coefficients, and an output;
a summing node including a plurality of inputs, each input coupled to an output of one of the r-parallel complex multipliers, the summing node further including a feedback input and including an output to provide a FFT; and
an accumulator including an input coupled to the output of the summing node and including an output coupled to the feedback input.

3. The circuit of claim 1, wherein the radix-r FFT processing element comprises:
a complex multiplier including a first input configured to receive one of the r equal sub-domains of the data, a second input configured to receive coefficients, and an output;
a summing node including an input coupled to an output of the complex multiplier, and including a feedback input and an output to provide a FFT; and
an accumulator including an input coupled to the output of the summing node and including an output coupled to the feedback input.

4. The circuit of claim 3, wherein the radix-r FFT processing element comprises a feedback loop coupled to the output of the summing node.

5. The circuit of claim 1, wherein the radix-r FFT processing element includes a first order radix-2 FFT processing element.

6. The circuit of claim 5, wherein the first order radix-2 FFT processing element includes 2N real multiplication operations and 3N real addition operations.

7. The circuit of claim 1, wherein the radix-r FFT processing element includes a second order radix-2 FFT processing element.

8. The circuit of claim 7, wherein the second order radix-2 FFT processing element includes N+2 real multiplication operations and 3N−2 real addition operations.

9. The circuit of claim 1, wherein the radix-r FFT processing element includes a first order radix-4 FFT processing element.

10. The circuit of claim 9, wherein the first order radix-4 FFT processing element includes N real multiplication operations and 5N/2 real addition operations.

11. The circuit of claim 1, wherein the radix-r FFT processing element includes a second order radix-4 FFT processing element.

12. The circuit of claim 7, wherein the second order radix-4 FFT processing element includes N/2+2 real multiplication operations and 5N/2−2 real addition operations.

13. A method comprising:
receiving a signal of size N;
dividing the signal by a number of radices of a fast Fourier Transform (FFT) filter to produce a number of signal portions (v);
process the number of signal portions in parallel to produce an output signal representing a selected frequency.

14. The method of claim 13, further comprising:
providing the number of signal portions to a first set of FFT filters to determine a first frequency parameter in a first dimension;
providing the number of signal portions to a second set of FFT filters to determine a second frequency parameter in a second dimension; and
determine the output signal based on the first frequency parameter and the second frequency parameter; and
wherein the output signal is two-dimensional

15. The method of claim 13, further comprising:
providing the number of signal portions to a first set of FFT filters to determine a first frequency parameter in a first dimension;
providing the number of signal portions to a second set of FFT filters to determine a second frequency parameter in a second dimension;
providing the number of signal portions to a third set of FFT filters to determine a third frequency parameter in a third dimension; and
determine the output signal based on the first frequency parameter, the second frequency parameter, and the third frequency parameter; and
wherein the output signal is three-dimensional

16. A circuit comprising:
an input configured to receive a signal; and
a radix-r fast Fourier transform (FFT) processing element coupled to the input and configured to subdivide data of size N into r equal sub-domains of size N/r−1, to process the r equal subdomains in parallel to determine r specific frequencies; and
a radix-r butterfly to combine the r specific frequencies to determine an output frequency.

17. The circuit of claim 16, wherein the radix-r FFT processing element comprises:
r parallel complex multipliers, each of the r parallel complex multipliers including a first input configured to receive one of the r equal sub-domains of the data, a second input configured to receive coefficients, and an output;
a summing node including a plurality of inputs, each input coupled to an output of one of the r-parallel complex multipliers, the summing node further including a feedback input and including an output to provide a FFT; and
an accumulator including an input coupled to the output of the summing node and including an output coupled to the feedback input.

18. The circuit of claim 16, wherein the radix-r FFT processing element comprises:
a complex multiplier including a first input configured to receive one of the r equal sub-domains of the data, a second input configured to receive coefficients, and an output;
a summing node including an input coupled to an output of the complex multiplier, and including a feedback input and an output to provide an FFT; and
an accumulator including an input coupled to the output of the summing node and including an output coupled to the feedback input.

19. The circuit of claim 16, wherein the radix-r FFT processing element comprises:
a first set of r parallel complex multipliers, each of the r parallel complex multipliers including a first input configured to receive one of the r equal sub-domains of the data, a second input configured to receive coefficients, and an output;
a second set of r-parallel complex multipliers, each of the r parallel complex multipliers including a first input configured to receive one of the r equal sub-domains of the data, a second input configured to receive coefficients, and an output; and
wherein the output frequency is two dimensional.

20. The circuit of claim 16, wherein the radix-r FFT processing element comprises:
a first set of r parallel complex multipliers, each of the r parallel complex multipliers including a first input configured to receive one of the r equal sub-domains of the data, a second input configured to receive coefficients, and an output;
a second set of r-parallel complex multipliers, each of the r parallel complex multipliers including a first input configured to receive one of the r equal sub-domains of the data, a second input configured to receive coefficients, and an output;
a third set of r-parallel complex multipliers, each of the r parallel complex multipliers including a first input configured to receive one of the r equal sub-domains of the data, a second input configured to receive coefficients, and an output; and
wherein the output frequency is three dimensional.
